(19) United States
(12) Patent Application Publication
(10) Pub. No.: US 2026/0033380 A1
(43) Pub. Date: Jan. 29, 2026

(54) ENCAPSULATED PACKAGE HAVING TIE BAR EXPOSED AT STEPPED SIDEWALL WITH NOTCH

(71) Applicant: Infineon Technologies AG, Neubiberg (DE)

(72) Inventors: Meng How CHONG, Melaka (MY); Aira Lourdes Baring VILLAMOR, Melaka (MY); Emmanuel Inoferio LIVELO, Melaka (MY)

(73) Assignee: Infineon Technologies AG, Neubiberg (DE)

(21) Appl. No.: 19/235,798

(22) Filed: Jun. 12, 2025

(30) Foreign Application Priority Data
Jul. 26, 2024 (DE) 10 2024 207 040.8

(51) Int. Cl. H01L 23/31; H01L 21/48; H01L 21/56; H01L 23/00; H01L 23/495; H01L 23/498; H01L 25/07; H10D 80/20

(52) U.S. Cl. CPC H01L 23/3121; H01L 21/4842; H01L 21/561; H01L 21/565; H01L 23/49503; H01L 23/49562; H01L 23/49811; H01L 24/32; H01L 24/96; H01L 24/97; H01L 25/072; H01L 2224/32245; H01L 2224/96; H01L 2224/97; H01L 2924/1815; H10D 80/251

(57) ABSTRACT

A package and method is disclosed. In one example, the package comprises a carrier comprising a component mounting area from which a tie bar extends, the tie bar being configured for being clamped by an encapsulation tool pin during encapsulation, an electronic component mounted on the component mounting area, and an encapsulant encapsulating at least part of the electronic component and at least part of the carrier, wherein a sidewall of the package has a step between a first vertical sidewall section and a second vertical sidewall section; wherein the first vertical sidewall section has a notch in the encapsulant and a part of the second vertical sidewall section exposes the tie bar.

### CROSS-REFERENCE TO RELATED APPLICATION

This Utility Patent application claims priority to German Patent Application No. 10 2024 207 040.8 filed Jul. 26, 2024, which is incorporated herein by reference.

### BACKGROUND

### Technical Field

Various embodiments relate generally to a package, and a method of manufacturing a package.

### Description of the Related Art

Packages may be denoted as encapsulated electronic components with electrical connections extending out of the encapsulant and being mountable on an electronic periphery, for instance on a printed circuit board.

Packaging cost is an important driver for the industry. Related with this are performance, dimensions and reliability. The different packaging solutions are manifold and have to address the needs of the application.

### SUMMARY

There may be a need to provide a possibility to manufacture packages with high device reliability and in a simple and quick way.

According to an exemplary embodiment, a package is provided which comprises a carrier comprising a component mounting area from which a tie bar extends, the tie bar being configured for being clamped by an encapsulation tool pin during encapsulation, an electronic component mounted on the component mounting area, and an encapsulant encapsulating at least part of the electronic component and at least part of the carrier, wherein a sidewall of the package has a step between a first vertical sidewall section and a second vertical sidewall section, wherein the first vertical sidewall section has a notch in the encapsulant and a part of the second vertical sidewall section exposes the tie bar.

According to another exemplary embodiment, a method of manufacturing a package is provided, wherein the method comprises providing a carrier comprising a component mounting area from which a tie bar extends, mounting an electronic component on the component mounting area, encapsulating at least part of the electronic component and at least part of the carrier by an encapsulant, wherein the tie bar is clamped by an encapsulation tool pin during at least part of the encapsulating, forming the package with a sidewall which has a step between a first vertical sidewall section and a second vertical sidewall section, forming the first vertical sidewall section with a notch in the encapsulant, and exposing the tie bar at a part of the second vertical sidewall section.

According to an exemplary embodiment, an encapsulated (in particular molded) package is provided which has a carrier (which may be made for instance of a metallic material, in particular based on a leadframe structure) with a component mounting area (such as a die pad) carrying at least one electronic component (such as a semiconductor chip). At least one tie bar may extend laterally from the component mounting area. The tic bar may have the function to connect neighbored carriers or component mounting areas of an integrated carrier structure before singulation to thereby provide stability. In addition, the tie bar may be used to be clamped down by an encapsulation tool pin during the process of encapsulating carrier and electronic component by an encapsulant (such as a mold compound). This clamping of the tie bar together with the component mounting area of the carrier may prevent an undesired flow of still flowable encapsulant to the bottom side of the carrier which may allow to avoid undesired phenomena such as mold flash or bleeding of encapsulant material into unintentional regions of the package. As a fingerprint of the temporary presence of the encapsulation tool pin during at least part of an encapsulation process, the encapsulant encapsulating electronic component and carrier may have a sidewall with a notch where a portion of the encapsulation tool pin has been located during encapsulation. More specifically, a spatial region where the encapsulation tool pin has been positioned during encapsulation may first lead to a hole in the encapsulant having an inverse shape as the encapsulation tool pin which may be retracted at the end of an encapsulation process. In a singulation process of singulating individual packages after encapsulation, encapsulant material adjacent to such a hole may be removed together with tie bar material, for instance by a mechanical sawing process using two different blades with different dimensions. Advantageously, a sidewall of the package has a step between a first vertical sidewall section and a second vertical sidewall section. The first vertical sidewall section may have the notch in the encapsulant in a region where the encapsulation tool pin has been present during the encapsulation process. Furthermore, a part of the second vertical sidewall section may expose a flange face of the tie bar. One of the vertical sidewall portions may be defined by a first dicing blade, whereas the other vertical sidewall portion may be defined by a second dicing blade with a different dimension. The above-described material removal may convert the inverse pin-shaped hole into the notch-shaped sidewall recess in the encapsulant and may expose the tie bar. For example, the notch may be vertically and horizontally displaced with respect to an exposed lateral surface of the tie bar. Moreover, the notch may be arranged at one side of the step, whereas the exposed tie bar may be arranged on the other side of the step. This may be ensured by the two different dicing blades with different geometric properties cutting through encapsulant and tie bar material one after the other. As a result of such package design and manufacturing architecture, undesired burrs may be reliably prevented in the notch, which burrs may be generated when sawing through the tie bar, which may be metallic. Due to the described package architecture and corresponding manufacturing process, artefacts such as mold flash and/or burrs in the recess may be efficiently suppressed, while simultaneously allowing a simple and efficient manufacture of the package. As a result, packages may be provided which can be manufactured with high device reliability and in a simple and quick way.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a three-dimensional view of a package according to an exemplary embodiment.

FIG. 2 illustrates a top view of the package according to FIG. 1.

FIG. 3 illustrates a bottom view of the package according to FIG. 1.

FIG. 4 illustrates a front side view of the package according to FIG. 1.

FIG. 5 illustrates a back side view of the package according to FIG. 1.

FIG. 6 illustrates a detailed side view of the package according to FIG. 1.

FIG. 7 illustrates a preform of packages during a batch manufacture according to an exemplary embodiment.

FIG. 8 illustrates a three-dimensional view of a plurality of preforms of packages as well as a detail during a batch manufacturing process according to an exemplary embodiment.

FIG. 9 illustrates an encapsulation tool used for manufacturing a package according to an exemplary embodiment.

FIG. 10 illustrates a side view of an arrangement during manufacture of packages using different dicing blades according to an exemplary embodiment.

### DETAILED DESCRIPTION

There may be a need to provide a possibility to manufacture packages with high device reliability and in a simple and quick way.

According to an exemplary embodiment, a package is provided which comprises a carrier comprising a component mounting area from which a tie bar extends, the tie bar being configured for being clamped by an encapsulation tool pin during encapsulation, an electronic component mounted on the component mounting area, and an encapsulant encapsulating at least part of the electronic component and at least part of the carrier, wherein a sidewall of the package has a step between a first vertical sidewall section and a second vertical sidewall section, wherein the first vertical sidewall section has a notch in the encapsulant and a part of the second vertical sidewall section exposes the tie bar.

According to another exemplary embodiment, a method of manufacturing a package is provided, wherein the method comprises providing a carrier comprising a component mounting area from which a tie bar extends, mounting an electronic component on the component mounting area, encapsulating at least part of the electronic component and at least part of the carrier by an encapsulant, wherein the tie bar is clamped by an encapsulation tool pin during at least part of the encapsulating, forming the package with a sidewall which has a step between a first vertical sidewall section and a second vertical sidewall section, forming the first vertical sidewall section with a notch in the encapsulant, and exposing the tie bar at a part of the second vertical sidewall section.

According to an exemplary embodiment, an encapsulated (in particular molded) package is provided which has a carrier (which may be made for instance of a metallic material, in particular based on a leadframe structure) with a component mounting area (such as a die pad) carrying at least one electronic component (such as a semiconductor chip). At least one tie bar may extend laterally from the component mounting area. The tic bar may have the function to connect neighbored carriers or component mounting areas of an integrated carrier structure before singulation to thereby provide stability. In addition, the tie bar may be used to be clamped down by an encapsulation tool pin during the process of encapsulating carrier and electronic component by an encapsulant (such as a mold compound). This clamping of the tie bar together with the component mounting area of the carrier may prevent an undesired flow of still flowable encapsulant to the bottom side of the carrier which may allow to avoid undesired phenomena such as mold flash or bleeding of encapsulant material into unintentional regions of the package. As a fingerprint of the temporary presence of the encapsulation tool pin during at least part of an encapsulation process, the encapsulant encapsulating electronic component and carrier may have a sidewall with a notch where a portion of the encapsulation tool pin has been located during encapsulation. More specifically, a spatial region where the encapsulation tool pin has been positioned during encapsulation may first lead to a hole in the encapsulant having an inverse shape as the encapsulation tool pin which may be retracted at the end of an encapsulation process. In a singulation process of singulating individual packages after encapsulation, encapsulant material adjacent to such a hole may be removed together with tie bar material, for instance by a mechanical sawing process using two different blades with different dimensions. Advantageously, a sidewall of the package has a step between a first vertical sidewall section and a second vertical sidewall section. The first vertical sidewall section may have the notch in the encapsulant in a region where the encapsulation tool pin has been present during the encapsulation process. Furthermore, a part of the second vertical sidewall section may expose a flange face of the tie bar. One of the vertical sidewall portions may be defined by a first dicing blade, whereas the other vertical sidewall portion may be defined by a second dicing blade with a different dimension. The above-described material removal may convert the inverse pin-shaped hole into the notch-shaped sidewall recess in the encapsulant and may expose the tie bar. For example, the notch may be vertically and horizontally displaced with respect to an exposed lateral surface of the tie bar. Moreover, the notch may be arranged at one side of the step, whereas the exposed tie bar may be arranged on the other side of the step. This may be ensured by the two different dicing blades with different geometric properties cutting through encapsulant and tie bar material one after the other. As a result of such package design and manufacturing architecture, undesired burrs may be reliably prevented in the notch, which burrs may be generated when sawing through the tie bar, which may be metallic. Due to the described package architecture and corresponding manufacturing process, artefacts such as mold flash and/or burrs in the recess may be efficiently suppressed, while simultaneously allowing a simple and efficient manufacture of the package. As a result, packages may be provided which can be manufactured with high device reliability and in a simple and quick way.

### Description of Further Exemplary Embodiments

In the following, further exemplary embodiments of the package, and the method will be explained.

In the context of the present application, the term “package” may particularly denote an electronic device which may comprise one or more electronic components mounted on a carrier. Said constituents of the package may be encapsulated at least partially by an encapsulant. Optionally, one or more electrically conductive interconnect bodies (such as bond wires and/or clips) may be implemented in a package, for instance for electrically coupling the electronic component with the carrier and/or with leads.

In the context of the present application, the term “carrier” may particularly denote a support structure (which may be at least partially electrically conductive) which serves as a mechanical support for the one or more electronic components to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may comprise a die pad.

In the context of the present application, the term “component mounting area” may particularly denote a section of the carrier which is configured for mounting at least one electronic component thereon. For instance, the component mounting area may be a die pad. In an embodiment, the component mounting area may be a planar plate-like metallic body or region.

In the context of the present application, the term “tie bar” may particularly denote a web, beam or bar which may extend from a component mounting area of a carrier. For example, such a tie bar may be made of the same material as the component mounting area and may be integrally connected with the component mounting area. Such a tie bar may be provided for connection of said component mounting area of the carrier with another component mounting area of an adjacent carrier of a multi-carrier structure such as a leadframe. Hence, such a tie bar may be used for integrally connecting various carriers in a common carrier structure (such as a leadframe) prior to singulation into individual packages. Thus, said tie bar may connect different carriers of a leadframe and may thereby increase the mechanical stability during manufacture. As a consequence, highly accurate packages may be obtained.

In the context of the present application, the term “clamping the tie bar by an encapsulation tool pin” may particularly denote a process during which a stationary, retractable, liftable or removable encapsulation tool pin of an encapsulation tool (for instance a mold tool) may press the tie bar of the carrier against a support surface (for instance of the encapsulation tool) during the encapsulation process to thereby clamp the tie bar together with the component mounting area onto the support surface for preventing flow of encapsulant material to an opposing side of the carrier. This may suppress encapsulation artefacts, such as mold flash.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), a light emitting, semiconductor-based device (such as a light emitting diode (LED) or LASER), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed in silicon technology, gallium nitride technology, silicon carbide technology, etc.

In the context of the present application, the term “encapsulant” may particularly denote a substantially electrically insulating material surrounding at least part of an electronic component and part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity.

In the context of the present application, the term “step between a first vertical sidewall section and a second vertical sidewall section” may particularly denote a structural discontinuity between a first vertical portion of the sidewall and another second vertical portion of the sidewall of the package. At the step, the vertical property of the sidewall may be interrupted. For instance, a horizontal sidewall section, a slanted sidewall section and/or a curved sidewall section between the first and second vertical sidewall sections may define at least one step. Also multiple steps are possible at said sidewall between the first and second vertical sidewall sections. The step may extend over the entire width of said sidewall, or over only part thereof. For instance, the step may also involve a local protrusion and/or a local indentation at said sidewall.

In the context of the present application, the term “notch” may particularly denote a sidewall recess. The notch may be defined in a (preferably vertical) encapsulant sidewall portion in which a hole is formed extending from one main surface of the encapsulant and ending vertically displaced with respect to the tie bar, i.e. the hole does not extend up to the tie bar. For instance, such a notch may be a blind hole in a sidewall. Such a notch may be delimited exclusively by encapsulant material (and in particular not by tie bar material).

In an embodiment, the sidewall has a horizontal sidewall section between the first vertical sidewall section and the second vertical sidewall section. For example, a top-sided vertical sidewall section may end at the horizontal sidewall section, by which the step may be formed, which extends the sidewall to define an indentation or a protrusion in form of another sidewall section. Thus, the sidewall may be defined by two horizontally spaced parallel vertical sidewall sections between which the horizontal sidewall section is interposed.

In an embodiment, said horizontal sidewall section is delimited exclusively by material of the encapsulant. Consequently, a dicing process of a two-stage dicing sequence defining said horizontal sidewall section needs to cut, in this portion, only through relatively soft encapsulant material. Consequently, a corresponding dicing process may be executed in a fast way.

In an embodiment, said step extends entirely between two further sidewalls of the package connected to said sidewall. The step can be defined by a dicing street along which a dicing blade moves and cuts during a dicing process of a two-stage dicing sequence. Such a straight dicing street may lead to a sidewall step extending continuously from one end to the other and of said sidewall. Hence, the step may extend straight along the entire breadth of the sidewall.

In an embodiment, said notch is delimited by a curved delimiting surface. For instance, the encapsulation tool pin may have a round shape along its circumference or around its lateral area. The encapsulation tool pin may also taper towards the tie bar. Consequently, a hole in the encapsulant may be for example frustoconical or cylindrical. After cutting by a cutting blade during dicing the encapsulant surface delimiting the notch may be curved as well.

In an embodiment, said notch is tapering towards the step. This geometry is the fingerprint of an encapsulation tool pin with tapering end section extending into the encapsulant and pressing on a tie bar during the manufacturing process. Even when a resulting circumferentially closed blind hole in the encapsulant is converted into a sidewall recess by a mechanical sawing process, the tapering characteristics may be maintained for the sidewall notch.

In an embodiment, an exposed surface of said tie bar extends from an upper end of said second vertical sidewall section towards the step. A removal of metallic material of the tie bar and of surrounding encapsulant material may be accomplished, during the manufacturing process, by a first dicing blade having a larger dimension than a second dicing blade forming the notch in the first vertical sidewall section. This formation of the step accompanied by removal of metallic tie bar material may also prevent that, during the dicing process, debris enters into the notch. Descriptively speaking, this can also be promoted by the spatial distance between the exposed tie bar surface and the notch surface thanks to the step.

In an embodiment, said exposed surface of tie bar extends towards but not up to the step. Thus, the step may remain spaced with respect to the exposed tie bar surface. This can be achieved when the aforementioned first dicing process cuts through the entire tic bar and vertically beyond it into the encapsulant, so as to reliably ensure a complete removal of the corresponding tie bar material even considering tolerances.

In an embodiment, the notch and an exposed surface of the tie bar are in flush in a plan view on said sidewall. In particular, an extrapolated central axis of the notch may extend through the tie bar in a plan view on the sidewall.

In an embodiment, the carrier comprises a further tie bar extending from the component mounting area and configured for being clamped by a further encapsulation tool pin during encapsulation, wherein another sidewall of the package has another step between another first vertical sidewall section and another second vertical sidewall section, wherein the other first vertical sidewall section has another notch in the encapsulant and a part of the other second vertical sidewall section exposes the other tie bar. When providing a plurality of tie bars which can be clamped onto a counter surface by an encapsulation tool pin or the like during encapsulation, undesired tilting of the component mounting area of the carrier can be inhibited even more reliably or efficiently. The different tic bars may extend from different edges of the component mounting area for a more balanced pressing characteristics. The features described herein for the sidewall with exposed tie bar may apply also to the other sidewall with exposed further tic bar.

In an embodiment, the tie bar and the further tie bar extend from opposing sides of the component mounting area, wherein the sidewall and the other sidewall are opposing sidewalls of the package. To put it shortly, the above described geometry of sidewall, vertical sidewall sections, step, notch and tie bar may be realized in the same fashion at an opposing sidewall with an opposing step, opposing vertical sidewall sections, an opposing notch and an opposing tie bar. For example, the sidewall and the other sidewall including the tic bar and the further tie bar, respectively, may have the same shape and dimensions for obtaining a symmetrical package architecture. For instance, two of four side edges of a substantially rectangular component mounting area may be provided for forming tie bars, whereas the other two side edges may be configured for providing or connecting leads or lead sections. This may result in a compact design of the package.

In an embodiment, it is possible that at least two tie bars extend side-by-side (and for example parallel to each other) from the same edge of the component mounting area. This may further reinforce the connection between adjacent carriers in a batch manufacturing architecture and may provide an even more reliable suppression of mold flash or bleeding, etc. It may then also be possible that each of said tie bars extending from the same edge of the component mounting area is clamped by a respective encapsulation tool pin during encapsulation. Consequently, an assigned sidewall of the package may comprise a plurality of notches (each resulting from a respective encapsulation tool pin) in the first vertical sidewall section and a plurality of exposed tie bars in the second vertical sidewall section being separated from the first vertical sidewall section by a step.

In an embodiment, the sidewall is delimited exclusively by material of the encapsulant and of the tic bar. Thus, the at least one sidewall, which may be a sawn side flank of the package, may be defined, in particular exclusively, by the encapsulant and a (in particular metallic) tie bar connected to the component mounting area of the carrier. The tie bar may be used for integrally connecting various carriers in a common carrier structure (such as a leadframe) prior to singulation into individual packages and may therefore be partially exposed upon singulation. More specifically, the first vertical sidewall section with the notch may be delimited exclusively by encapsulant material, whereas the second vertical sidewall section with the exposed tie bar may be delimited predominantly by encapsulant material and additionally by exposed tie bar material (which may be a metal). The step, in particular realized by a horizontal sidewall section between the aforementioned vertical sidewall sections, may also be defined by encapsulant material only.

In an embodiment, the package comprises one or more electrically conductive lead sections, in particular at least one of which being integrally formed with the component mounting area and/or at least one of which being formed separately from the component mounting area, extending out of the encapsulant at one or two slanted sidewalls of the encapsulant, said one or two slanted sidewalls in particular having a molded texture. Each lead section may comprise one or more leads. At least one lead section may be integrally formed with the component mounting area and the tie bar(s). Additionally or alternatively, at least one lead section may be formed as a separate body with respect to the component mounting area and the tie bar(s), and may be electrically coupled with the component mounting area and/or at least one electronic component mounted thereon by one or more electrically conductive connection structures (such as bond wires and/or clips). For example, lead sections may be arranged along edges of the component mounting area at which no tie bars are present. In the context of the present application, the term “lead” may in particular denote an electrically conductive (for instance strip shaped) element (which may be planar or bent) which may be assigned functionally to the carrier and which serves for contacting the electronic component with an exterior of the package. For instance, a lead may be partially encapsulated and partially exposed with respect to an encapsulant. When the carrier forms part of a leadframe, leads may surround a die pad of the carrier, for instance at two opposing sides. The one or more leads may or may not form part of the carrier.

In an embodiment, a main surface of the component mounting area facing away from the electronic component is at least partially exposed with respect to the encapsulant. Such an exposed main surface of the carrier's component mounting area may allow to efficiently remove heat generated by the at least one electronic component during operation of the package. Since the carrier may be made partially or entirely from a metallic material which may also have a high thermal conductivity, heat removal by an exposed carrier surface may be much more efficient than through material of the encapsulant, having usually a significantly lower thermal conductivity than the carrier. When the carrier is exposed with respect to the encapsulant at one main surface of the package, an exposed electrically conductive surface may be provided which may simplify electrically connecting the package and which may also promote heat dissipation during operation of the package (in particular when the electronic component is a power semiconductor chip).

In an embodiment, the sidewall (having the first and second vertical sidewall sections and the step in between, as well as the notch and the exposed tie bar) has a sawn texture. Correspondingly, the method may comprise forming said sidewall by mechanically sawing. In the context of the present application, the term “sawn texture” of said sidewall may particularly denote a surface structure or surface profile on a surface of said sidewall being defined by sawing. Preferably, said sawing process is a mechanical sawing process using two saw blades one after the other in a two-stage dicing process. Alternatively, also laser sawing is possible. Due to such a sawing process, in particular mechanical sawing process using sequentially two saw blades with different dimensions in a sawing street, a rough surface texture of encapsulant material (in particular having a roughness Ra of more than 0.8 μm, in particular between 0.8 μm and 5 μm, for instance around 1 μm) is obtained. Such a rough characteristic of a sawn side flank is combined with the formation of microscopic scratches, marks, rills or corrugations formed by the sawing tools. For instance, a respective mechanical saw blade may have polyimide bound diamond bodies used for sawing which may for example create the mentioned sawn texture. In particular, a sawn texture of the at least one side flank may comprise a roughness Ra of more than 0.8 μm in combination with corrugations having larger dimensions compared to dimensions of protrusions and indentations relating to a said roughness. The roughness of a surface may be defined as and may be measured as the centerline average height Ra. Ra is the arithmetic mean value of all distances of the profile from the centerline. For instance, the measurement or determination of roughness Ra of the sawn surface may be carried out according to DIN EN ISO 4287:2010. A saw used for forming the sawn texture may be denoted as a tool comprising a first and a second tough saw blade with a hard-toothed edge. Such a saw may be used to cut through encapsulant material and optionally also through metallic material of the one or more tie bars by placing the respective tooth edge against the material and moving it forcefully forth and less forcefully back or continuously forward. For instance, a first and a second powered circular saw blade may be used for this purpose. At a sawn side flank of an encapsulant, in particular a sawn side flank of a mold compound, a broken surface may be obtained at which also filler particles are sawn at the surface of the sawn side flank. As a consequence, a sawn side flank may be defined by material of the above-described matrix of the encapsulant and partially also by cut non-coated filler particles.

In an embodiment, the method comprises subjecting a pre-form of the package to a first dicing process using a first dicing blade for removing a part of material of the tic bar, and thereafter subjecting the pre-form of the package to a second dicing process using a second dicing blade for removing a part of material of the encapsulant. The first dicing blade may be controlled for cutting substantially through tie bar material between two adjacent packages manufactured in a batch process. This first cutting process may also convert a blind hole formed in the encapsulant after removal of an encapsulation tool pin into a through hole. The first cutting process may define the second vertical sidewall section as well as a horizontal sidewall section at the step. This first dicing blade may cut along a dicing street which is wider than a dicing street along which the second dicing blade cuts during a second subsequent cutting process after the cutting by the first dicing blade. Consequently, the tie bar material remaining after the cutting process by the first dicing blade may be located spatially remote from the encapsulant hole caused by the encapsulation tool pin. The second cutting process may then cut through the entire remaining thickness of the encapsulant so as to convert the through hole into the notch while defining the first vertical sidewall section. Due to the narrower and deeper dicing street corresponding to the narrower second dicing blade compared with the wider and shallower dicing street corresponding to the wider first dicing blade, the formed sidewall is provided with the first and second vertical sidewall sections with step in between, wherein one of said vertical sidewall sections exposes the tie bar and the other one has a notch. Moreover, the described configuration of the two dicing blades may lead to a package which does not (or at least not excessively) have tie bar debris in the notch.

In an embodiment, the method comprises providing the first dicing blade of a first width and the second dicing blade of a second width smaller than the first width. This configuration of the two dicing blades in combination with a shallower cutting by the first dicing blade compared with a deeper cutting by the second dicing blade may ensure step formation and avoidance of (for example copper) debris in the pin hole and later in the notch.

In an embodiment, a first width of the first dicing blade is larger than a pin width of the encapsulation tool pin. This may promote the formation of the above-described step. Advantageously, this may lead, in a cross-sectional view, to a stepped configuration between a pin hole and recess formed in the tie bar and optionally a portion of the encapsulant by the first dicing blade.

In an embodiment, said first width is more than 0.5 mm and/or said pin width is not more than 0.5 mm. For instance, the above-mentioned second width may be not more than 0.4 mm. For example, the first width may be 0.55 mm, whereas the pin width may be 0.5 mm. For instance, the second width may be 0.3 mm.

In an embodiment, the method comprises providing an oblong carrier structure comprising the carrier and at least one additional carrier comprising at least one additional component mounting area from which at least one additional tie bar extends, mounting at least one additional electronic component on the at least one additional component mounting area, encapsulating at least part of the at least one additional electronic component and part of the at least one additional carrier by an oblong encapsulant structure to which also said encapsulant belongs, wherein the at least one additional tie bar is clamped by at least one additional tool pin during at least part of the encapsulating, and separating an obtained structure into individual packages each comprising a respective one of said carriers, a respective one of said electronic components, and a part of said encapsulant structure as a respective encapsulant, so that each of the packages is formed with a respective sidewall which has a respective step between a respective first vertical sidewall section and a respective second vertical sidewall section, wherein the respective first vertical sidewall section has a respective notch in the respective encapsulant and a part of the respective second vertical sidewall section exposes the respective tie bar. Thus, multiple packages may be formed in a batch process. Such a batch process may use integral oblong carrier structures having a plurality of carriers connected by tic bars. Moreover, such a batch process may use integral oblong encapsulant structures providing encapsulants for multiple packages. In a singulation process, the oblong carrier structure may be separated into individual carriers and the oblong encapsulant structure may be separated into individual encapsulants, thereby providing a plurality of individual packages. During the separation, each oblong encapsulant structure may be cut by a two-stage dicing process combining a first wider and shallower cutting by a first dicing blade with a second narrower and deeper cutting by a second dicing blade to thereby form a respective sidewall with two mutually horizontally spaced vertical sidewall sections by a step in between.

Still referring to the previously described embodiment, the method may comprise mounting additional electronic components on additional (preferably electrically conductive) carriers (which may be designed as the carrier described above, in particular with one or more tie bars), so that the electronic components and the carriers are arranged in a plurality of rows and columns, encapsulating at least part of the additional carriers and the additional electronic components by additional encapsulant, and sawing sidewalls (each having two vertical sidewall sections with notch or exposed tie bar and with a step in between) of the encapsulant structure(s) to form separate encapsulants. It may also be possible to provide additional leads or lead sections and to punch leads or lead sections extending beyond the encapsulants. Thus, the manufacturing method may be carried out on leadframe or panel level, i.e. for multiple carriers and for multiple electronic components simultaneously. Such a batch process further reduces the manufacturing effort and allows manufacturing packages on an industrial scale. The carriers and consequently the packages may be arranged in a matrix-like way in rows and columns. Descriptively speaking, sawing may be carried out horizontally, i.e. along the rows, whereas punching may be carried out vertically, i.e. along the columns. In this way, a highly efficient manufacturing process may be obtained.

In particular, the method may comprise forming a plurality of parallel encapsulant structures or bars of material of the encapsulant and the additional encapsulant, wherein each encapsulant structure or bar at least partially encapsulates all carriers and all electronic components of a respective column. According to such a preferred embodiment, encapsulant structures or bars may be formed covering for instance all carriers and electronic components of a column of the matrix-like arrangement of preforms of packages simultaneously. As a result, an arrangement of parallel vertically extending encapsulant bars or structures may be obtained. This may be carried out highly advantageously by molding. In particular, the combination of the formation of vertically extending encapsulant bars with the horizontal extension of the leads or lead sections may be of utmost advantage.

In an embodiment, the method comprises forming another slanted sidewall of the encapsulant by a slanted sidewall of a cavity of an encapsulation tool. Hence, slanted sidewalls may be defined by the geometry of an encapsulation tool which may lead to a molded texture, whereas sidewalls with two vertical sidewall sections and a step in between may be defined by a two-stage or two-blade mechanically dicing process which may result in a sawn texture.

In an embodiment, the method comprises punching lead sections extending beyond the encapsulant and being electrically coupled with the carrier and/or the electronic component. Said punching may lead to a punched surface. In the context of the present application, the term “punched surface” may particularly denote a surface area delimiting the one or more leads and being defined by punching. Punching may denote a forming process that uses a punch press to force a tool, which may be denoted as a punch, through the workpiece to create a hole via shearing. Punching is applicable to a wide variety of materials in sheet form, including sheet metal. Punching is a simple and therefore highly efficient method of defining structures in a patterned sheet material. Correspondingly, a punched surface is a surface defined by punching. A person skilled in the art will understand that a punched surface has dedicated properties which can be easily and unambiguously analysed by a person skilled in the art. At the punched surface delimiting the lead, a corresponding side flank of the encapsulant may be defined by the encapsulation process, in particular by molding. A corresponding encapsulant, such as a mold compound, may comprise a matrix (for instance comprising a resin) with filler particles. At a molded surface corresponding to a punched surface of the leads, the filler particles are coated by matrix material of the in particular mold compound-type encapsulant to form a defined structure with coated pixels on the surface. Moreover, a molded side flank at a punched surface of a corresponding lead may be slanted (for instance with a slanting angle in a range between 6° and 12°, in particular between 8° and 10°) for promoting removal of a corresponding mold body out of a mold tool.

In an embodiment, the method comprises clamping on the tie bar by the encapsulation tool pin during encapsulation so that the component mounting area is pressed onto a counter surface of an encapsulation tool. This may prevent the carrier from tilting during the encapsulation process so that an unintentional flow of encapsulant to the back side of the carrier may be reliably prevented. Hence, undesired phenomena such as mold flash or bleeding may be inhibited.

In an embodiment, the sidewall recess is a through hole-notch. Such a through hole-notch does not have a closed bottom. One open end of said through hole-notch may delimit one main surface of the package. An opposing other open end of said through hole-type notch may delimit a horizontal sidewall section at the step. The through hole-type notch may extend vertically over the entire extension of the first vertical sidewall section.

In an embodiment, said one or two slanted sidewalls may have a molded texture. Correspondingly, the method may comprise forming a slanted sidewall of the encapsulant by a slanted sidewall of an encapsulation tool cavity. This may lead to a molded texture. In the context of the present application, the term “molded texture” may particularly denote a characteristic surface profile of a side flank formed by molding. In particular, such a molded texture may comprise a smooth surface (in particular having a lower surface roughness Ra than a side flank with a sawn texture) with microscopic surface pixels corresponding to filler particles added to a mold compound, appearing at an exterior surface of a mold-type encapsulant and being coated with molded encapsulant material (in particular mold resin).

In an embodiment, a leadframe structure may be used as carrier. In the context of the present application, the term “leadframe” may particularly denote a metal structure comprising an array of initially integrally connected carriers and leads for packages. The electronic components may be attached to the carriers of the leadframe, and then bond wires and/or clips may be provided for attaching pads of the electronic component to leads of the leadframe. Subsequently, the leadframe may be molded in a plastic case or any other encapsulant. Outside and/or inside of the leadframe, corresponding portions of the leadframe may be cut-off, thereby separating the respective leads and/or carriers. A leadframe may be composed of multiple carriers or leadframe structures for electronic components, wherein each carrier may have a component mounting area, at least one tic bar, and one or more leads or lead sections.

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

As substrate or wafer forming the basis of the electronic components, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in gallium nitride or silicon carbide technology.

For the encapsulating, a plastic-like material or a ceramic material which may be subsidized by encapsulant additives such as filler particles, additional resins or others may be used.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Mold flash may occur when manufacturing packages due to warpage and insufficient clamping to hold a die paddle as flat as possible during a mold process. This may lead to yield loss. A pin may be provided to clamp down a tie bar and improve the clamping to resolve mold flash issues. However, implementation of fix pins may generate another issue, since copper debris may trap inside the pin groove.

A manufacturing architecture for packages involves the formation of common encapsulant structures for a plurality of packages and the subsequent separation by sawing through encapsulant and metallic carrier structures as well as punching through lead structures. A corresponding molding process may be supported with mold pins holding tie bars during molding and includes a sawing process as the final singulation.

However, since a cavity is formed by the mold pins over the tie bars, during sawing, burrs from the tie bars may be stuck in these spaces. Thus, metal debris and/or burrs from tie bar may got stuck inside the package hole during package sawing. This may lead to packages with pronounced burrs which may be beyond an acceptable burr specification.

According to an exemplary embodiment, a package may be provided being encapsulated by an encapsulant, such as a mold compound. The package may have a preferably at least partially electrically conductive carrier having a component mounting area (like a die paddle). One or more electronic components, for instance a semiconductor power chip, may be assembled on the component mounting area. Tie bars may interconnect adjacent carriers of a multi-carrier structure, such as a leadframe for providing mechanical support during a batch manufacturing process. During the manufacturing process, the tic bar may be also used for clamping it down by an encapsulation tool pin against a counter surface of an encapsulation tool. This may avoid unintentional flow of flowable encapsulant material to the bottom of the carrier, thereby preventing mold flash or bleeding of encapsulant material. The temporary presence of the encapsulation tool pin inside the encapsulant may create a hole in the encapsulant having the same shape as the encapsulation tool pin which is removed after encapsulation. By mechanical singulation using for example two mechanical sawing blades, encapsulant material surrounding part of said hole may be removed as tie bar material will also be removed during singulation. As a result, the pin-shaped hole will be modified into the notch-shaped sidewall recess which may be delimited by encapsulant material only. Consequently, the notch may be located vertically and horizontally displaced with respect to the exposed tie bar area and may be defined by encapsulant material only. In a singulation process of singulating individual packages after encapsulation, encapsulant material adjacent to an encapsulation tool pin-formed hole may be removed together with tie bar material, for example by two-stage dicing with two different blades having different dimensions and/or geometry. Beneficially, a package sidewall may have a vertical-horizontal-vertical transition region forming a sidewall step. A resulting first vertical sidewall section on one side of the step may have the notch where the encapsulation tool pin has been present during the encapsulation process. Moreover, a second vertical sidewall section on the other side of the step may expose a lateral surface of the tie bar. One vertical sidewall portion may be formed by a first dicing blade, and the other vertical sidewall portion may be formed by a differently dimensioned second dicing blade. A partial encapsulant removal process may convert the tool pin-defined hole into the notch and may expose the tie bar. The two different dicing blades with different geometry may cut through encapsulant and tie bar. The described architecture may prevent burrs from being inserted in the notch. The described manufacturing architecture and corresponding package may strongly suppress artefacts like mold flash and/or burrs. The obtained package may be manufactured with excellent reliability and moderate effort.

Experiments and simulations have confirmed the absence of any noteworthy (in particular copper) debris in the pinhole-related notch(es) due to the packaging architecture of exemplary embodiments. For instance, such debris may be metal smearing extending into the groove or notch, wherein such debris may still be connected with the sawn tie bar.

Exemplary embodiments may prevent copper debris trap in pins groove. A corresponding manufacturing method may be configured to prevent copper debris to get trapped inside grooves of the pin by using a two-stage cutting concept. A cutting procedure may be carried out twice with two different dicing blades. In this context, the thickness of the first dicing blade may be bigger than the width of a pin groove and than the thickness of the second blade. Moreover, the first blade may cut a small depth (for instance with a cutting depth equal to a thickness of a tie bar, or slightly more). Advantageously, the width of the second blade may be less than the one of a pin groove and may create isolation by cutting entirely through a mold compound at a groove location. Beneficially, copper debris may be prevented from trapping inside the groove created by a mold pin. For instance, fixed mold pins may overcome mold flash, while still serving as clamping mechanism for a leadframe during mold transfer. Exemplary embodiments may solve both mold flash (from a mold process) and copper trapped (from a package sawing process).

Advantageously, exemplary embodiments may be executed for very different package types, for instance for large panels or large package design. Such embodiments may solve mold flash and copper trapped issue and may eliminate potential solder on board issues.

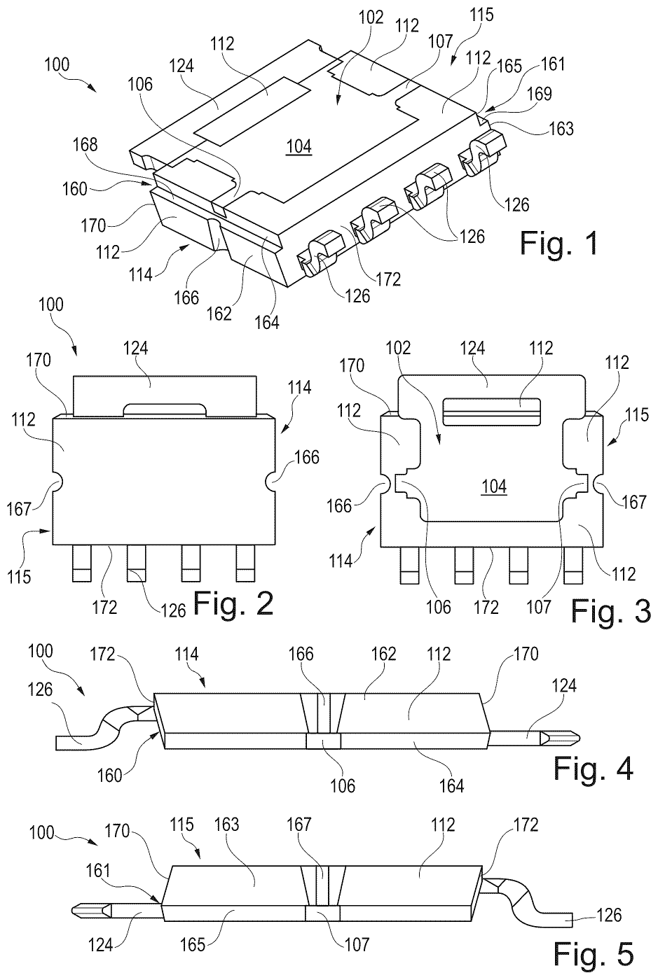

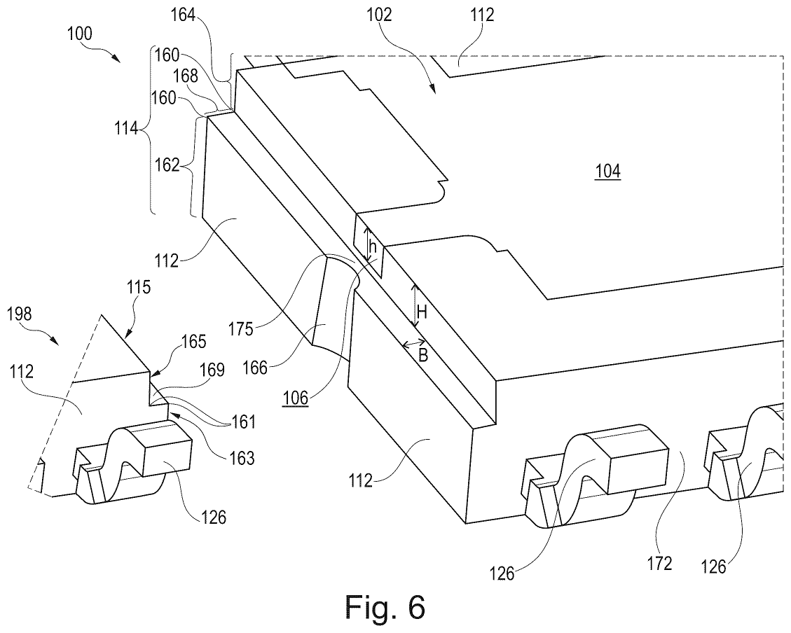

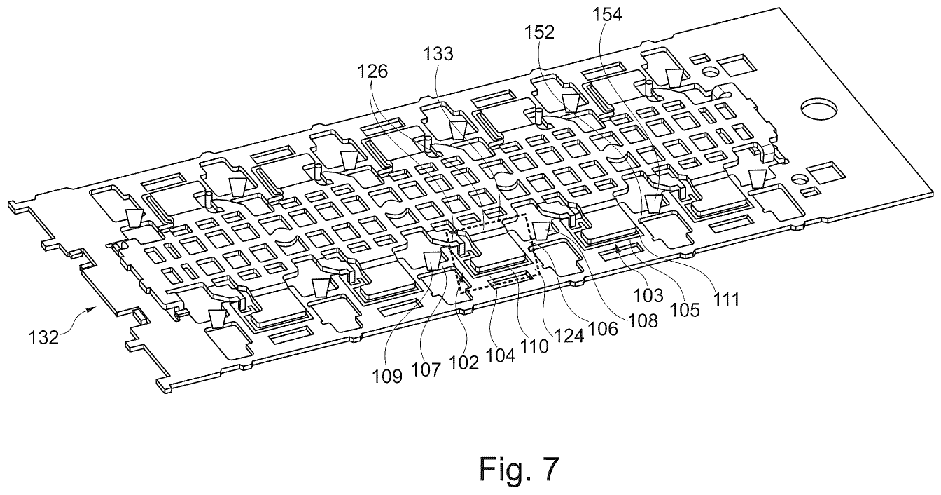

FIG. 1 illustrates a three-dimensional bottom-side view of a package 100 according to an exemplary embodiment. FIG. 2 illustrates a top view of the package 100 according to FIG. 1. FIG. 3 illustrates a bottom view of the package 100 according to FIG. 1. FIG. 4 illustrates a front side view of the package 100 according to FIG. 1. FIG. 5 illustrates a back side view of the package 100 according to FIG. 1. FIG. 6 illustrates a detailed side view of the package 100 according to FIG. 1. While FIG. 1 and FIG. 6 shows the design of package 100, FIG. 2 to FIG. 5 show actually manufactured versions of package 100. Since package 100 of FIG. 1 to FIG. 6 is already encapsulated by an encapsulant 112, so that the interior of the package 100 is not entirely visible in FIG. 1 to FIG. 6, reference is made additionally to encircled section 133 in FIG. 7 showing a portion of an interior of package 100 before encapsulation.

The package 100 according to FIG. 1 to FIG. 6 with an interior configuration as shown in FIG. 7 comprises a carrier 102, which may comprise or consist of a metal such as copper. For instance, said carrier 102 may be embodied as a leadframe structure. Since a portion of the carrier 102 is encapsulated by an encapsulant 112 (such as a mold compound), said portion of the carrier 102 is not visible in FIG. 1 to FIG. 6. The interior construction of the package 100 of FIG. 1 can however be better seen in FIG. 7 showing a preform from which the package 100 of FIG. 1 to FIG. 6 has been singulated after encapsulation. The carrier 102 comprises a component mounting area 104 which may be embodied as a die pad.

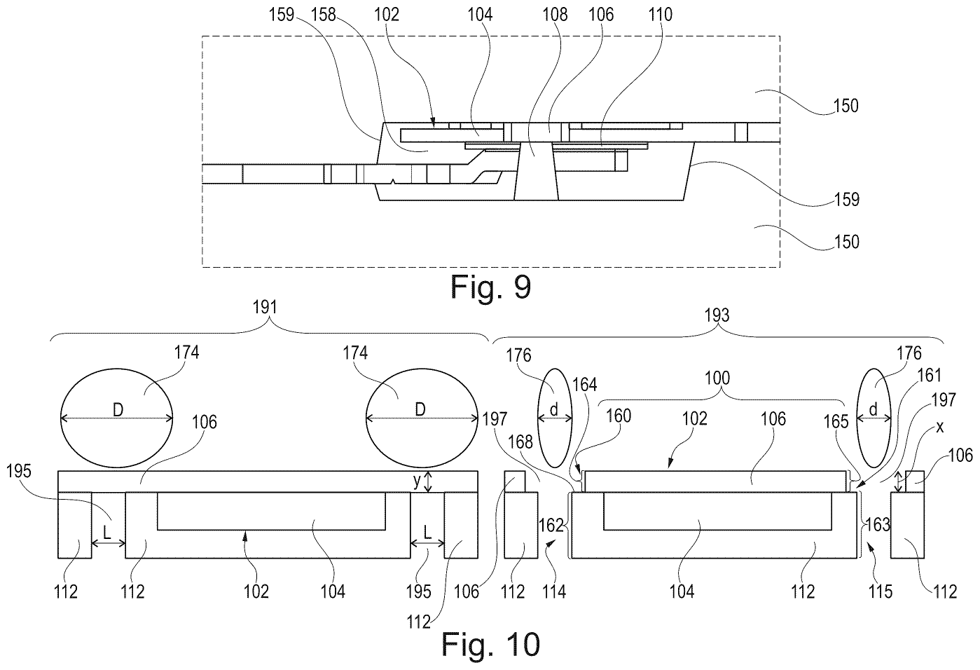

From a lateral side edge of the component mounting area 104, a tie bar 106 extends. For example, the component mounting area 104 and the tie bar 106 may be an integral metallic structure, for instance formed of copper material. The tie bar 106 may be configured for being clamped down by an encapsulation tool pin (see reference sign 108 in FIG. 7 or FIG. 9) during the process of encapsulation, i.e. during forming the encapsulant 112. This may prevent undesired mold flash or mold bleed at the side of the package 100 at which the component mounting area 104 is exposed beyond the encapsulant 112, which is the top side according to FIG. 1. As a consequence and as a fingerprint of this manufacturing process, the encapsulant 112 has a notch 166 in a sidewall 114 of the encapsulant 112, as explained below in further detail. The notch 166 is arranged where the encapsulation tool pin 108 had been present during the encapsulation process. Said notch 166 extends sidewise at a portion of sidewall 114 and into the encapsulant 112 and is completely delimited by material of the encapsulant 112 without reaching the tie bar 106. The tie bar 106 is exposed at vertical sidewall 114.

In a way as shown for instance in FIG. 7, an electronic component 110 may be mounted on the component mounting area 104. For instance, the electronic component 110 may be a semiconductor die, such as a power semiconductor die. The electronic component 110 may be assembled on the component mounting area 104 by an electrically conductive connection medium, such as a solder, a sinter material and/or electrically conductive glue. It is also possible that a plurality of electronic components are mounted on the component mounting area 104.

The already mentioned encapsulant 112 may encapsulate the electronic component 110 entirely and the carrier 102 partially. For instance, said encapsulant 112 may be a mold compound. Said encapsulant 112 may encapsulate the electronic component 110 and part of the carrier 102 and may have sidewall 114 with notch 166, wherein the tie bar 106 is exposed laterally at sidewall 114. The encapsulant 112 vertically covers an entire horizontal surface portion of the tie bar 106 facing the notch 166. Since the sidewall 114 is formed by mechanically dicing using two dicing blades (as explained below in further detail referring to FIG. 10), sidewall 114 has a sawn texture.

Referring again to FIG. 1 and FIG. 7, the carrier 102 may comprise a further tic bar 107 extending from the component mounting area 104 at an opposing side with respect to the tic bar 106. The further tie bar 107 is configured for being clamped by a further encapsulation tool pin 109, shown as well in FIG. 7, during encapsulation which may then be retracted after curing encapsulant 112 leaving a fully circumferentially closed blind hole behind. Said blind hole may be circumferentially delimited by the encapsulant 112 and may be delimited at a bottom side by the further tic bar 107. Thereafter, some material of encapsulant 112 and of the further tie bar 107 may also be removed during singulation, so that the encapsulant 112 is provided with a further sidewall 115 (which may be configured corresponding to vertical sidewall 114) with a further notch 167 (which may be embodied corresponding to notch 166), see FIG. 2 and FIG. 3. Again referring to FIG. 1 and FIG. 7, the tie bar 106 and the further tic bar 107 may extend from opposing sides of the component mounting area 104, and the sidewall 114 and the further sidewall 115 may be opposing sidewalls of the encapsulant 112 both having a sawn texture due to the mechanical dicing-type singulation process.

Next, sidewall 114 will be explained in detail referring to FIG. 6. As shown, said sidewall 114 may have a step 160 between a first vertical sidewall section 162 and a second vertical sidewall section 164 of the sidewall 114. More specifically, the first vertical sidewall section 162 may have the notch 166 extending laterally into the encapsulant 112. Moreover, a part of the second vertical sidewall section 164 exposes a vertical surface of the tie bar 106. As shown, the sidewall 114 may have a horizontal sidewall section 168 between the first vertical sidewall section 162 and the second vertical sidewall section 164. The step 160 may be formed where the horizontal sidewall section 168 connects the vertical sidewall sections 162, 164. Said horizontal sidewall section 168 may be delimited exclusively by material of the encapsulant 112. Also said first vertical sidewall section 162 may be delimited exclusively by material of the encapsulant 112. Said second vertical sidewall section 164 may be partially delimited by material of the encapsulant 112 and may be partially delimited by material of the tie bar 106. As shown as well, said step 160 extends entirely between two further sidewalls 170, 172 of the package 100 connected to said sidewall 114. In the shown embodiment, further sidewalls 170, 172 may be slanted rather than extending vertically. The step 160 on sidewall 114 extends straight along the entire horizontal path from sidewall 170 to sidewall 172. The horizontal sidewall section 168 displaces the first vertical sidewall section 162 with respect to the second vertical sidewall section 164 along a horizontal direction. Consequently, the first vertical sidewall section 162 extends further outwardly than the second vertical sidewall section 164.

The notch 166 formed in the first vertical sidewall section 162 and in the horizontal sidewall section 168 extends into the encapsulant 112 only to such an extent that a horizontal gap 175 remains between the notch 166 and the exposed surface of the tie bar 106. Said gap 175 may help to prevent debris or burrs which may be generated during sawing of the tie bar 106 from entering into notch 166. In a side view on the sidewall 114 according to FIG. 4, it can be seen that a center of the notch 166 and a center of the exposed tic bar 106 may be in alignment with each other. In other words, the notch 166 and an exposed surface of the tie bar 106 may be in flush in a plan view on said sidewall 114.

For example, a height, H, of the second vertical sidewall section 164 may be in a range from 0.1 mm to 1 mm, for instance 0.3 mm. For instance, a length, B, of the horizontal sidewall section 168 may be in a range from 0.1 mm to 1 mm, for instance 0.25 mm. For example, a height, h, of the exposed tie bar 106 may be in a range from 0.1 mm to 1 mm, for instance 0.25 mm. In order to comply with tolerances or as a safety measure, height H may be larger than height h, for instance may be at least 0.05 mm larger.

Again referring to FIG. 6, the notch 166 may be delimited by a curved delimiting surface. For instance, said notch 166 may be tapering towards the step 160. The latter may be the fingerprint of a tapering geometry of an encapsulation tool pin 108 used temporarily during the manufacturing process. In the shown embodiment, notch 166 is a through hole-notch which neither has a closed top nor a closed bottom. The bottom-sided open end of said through hole-notch 166 may delimit the bottom main surface of the package 100 according to FIG. 6. The opposing other open end of said through hole-type notch 166 may delimit the horizontal sidewall section 168 at the step 160, see again FIG. 6. Thus, the through hole-type notch 166 may extend vertically over the entire extension of the first vertical sidewall section 162.

Now referring to tie bar 106, one horizontal surface thereof may be located inside encapsulant 112, whereas the opposing other horizontal surface thereof is exposed, see FIG. 6. In addition, a vertical surface of said tie bar 106 is exposed at the second vertical sidewall section 164 of sidewall 114 and extends from an upper end of said second vertical sidewall section 164 towards, but not up to the step 160. Thus, the tie bar 106 may be both vertically and horizontally spaced with respect to the notch 166, which also inhibits entry of burrs or debris from tie bar 106 into the notch 166. Hence, the notch 166 is tapering from one main surface of the encapsulant 112 and of the package 100 as a whole towards, but not up to the tie bar 106. Thus, the tapering notch 166 vertically ends at a position where it does not reach the tie bar 106.

Referring to FIG. 1, FIG. 5 and in particular detail 198 of FIG. 6, the further sidewall 115 with the further notch 167 and the further exposed tie bar 107 may be configured in the same way (i.e. with corresponding first vertical sidewall section 163, corresponding second vertical sidewall section 165, corresponding step 161 and corresponding horizontal sidewall section 169) as described referring to FIG. 6 for the sidewall 114 with the notch 166 and the exposed tie bar 106.

Again referring to FIG. 1, the package 100 additionally comprises electrically conductive (preferably metallic, for instance made of copper) lead sections 124, 126 extending partially within and partially outside of the encapsulant 112. Lead section 124 may be integrally formed with the component mounting area 104. Lead section 126 may be a body being separate from the component mounting area 104, but may be electrically coupled with the electronic component 110 and/or with the component mounting area 104 by one or more electrically conductive connection elements (such as clips and/or bond wires). Both lead sections 124, 126 extend out of the encapsulant 112 at two opposing slanted sidewalls 170, 172 of the encapsulant 112. The slanted sidewalls 170, 172 may be defined by a profile of a cavity 158 of an encapsulation tool 150 (see FIG. 9) used for encapsulating package 100, i.e. used for forming encapsulant 112 (preferably by molding). Consequently, the surfaces of the two slanted sidewalls 170, 172 may have a molded texture being the fingerprint of the molding process executed for defining the slanted sidewalls 170, 172.

In contrast to this, the surfaces of the partially vertical and partially horizontal sidewalls 114, 115 are formed by sawing and therefore have a sawn texture. By inspecting the respective texture, a skilled person may distinguish between a sawn texture and a molded texture.

As shown in FIG. 1, a main surface of the component mounting area 104 facing away from the encapsulated electronic component 110 is exposed with respect to the encapsulant 112. Thus, heat dissipation from the encapsulated electronic component 110 can occur efficiently via the exposed highly thermally conductive surface of the component mounting area 104. Consequently, said main surface of package 100 may be denoted as heat sink side, since a heat sink (not shown) may be optionally attached to the heat dissipating exposed main surface of the component mounting area 104. For instance, such a heat sink may comprise a metallic plate to be attached to the exposed main surface of the component mounting area 104 with a plurality of cooling fins extending from said metallic plate.

The two opposing main surfaces of the package 100 may be parallel to each other. The predominantly vertical, but also partially horizontal sidewalls 114, 115 may extend predominantly perpendicular, and partially parallel to the main surfaces. The slanted sidewalls 170, 172 may be slanted with respect to the vertical sidewall sections 162-165 of the sidewalls 114, 115 and with respect to the main surfaces of the package 100. For instance, a slanting angle of the slanted sidewalls 170, 172 with respect to the vertical sidewall sections 162-165 of the sidewalls 114, 115 may be in a range from 6° to 12°.

With the described package design (compare FIG. 1 to FIG. 6) and corresponding manufacturing process (see FIG. 7 to FIG. 10, as described below in further detail), it may be possible that no (or at least no noteworthy) saw burrs get stuck in the cavity or notch 166 formed by the mold pin above the tie bar 106.

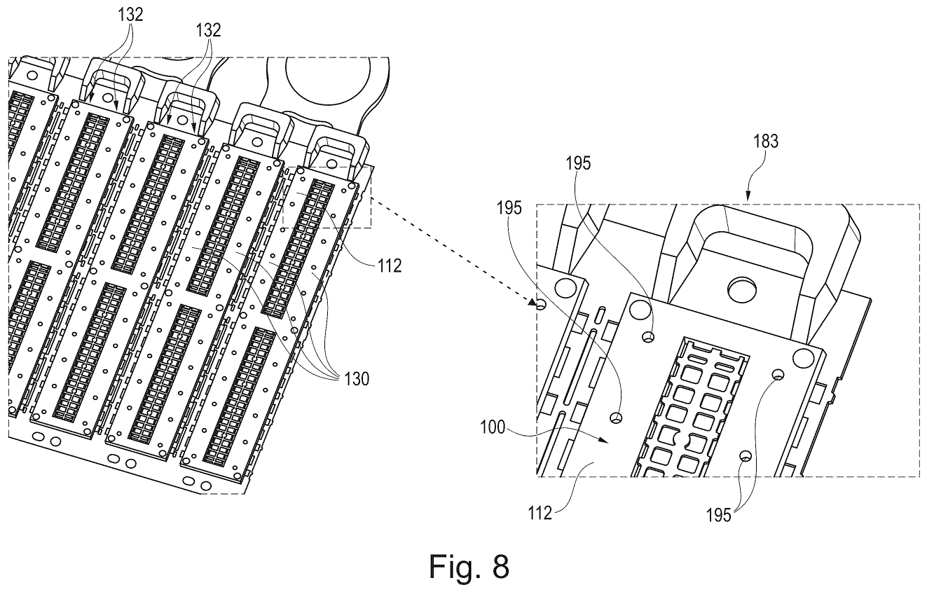

FIG. 7 illustrates a preform of packages 100 during a batch manufacture according to an exemplary embodiment before encapsulation. FIG. 8 illustrates a three-dimensional view of a plurality of preforms of packages 100 as well as a detail 183 during a batch manufacturing process according to an exemplary embodiment after encapsulation. FIG. 9 illustrates an encapsulation tool 150 used for manufacturing a package 100 according to an exemplary embodiment.

For manufacturing packages 100, a plurality of carriers 102, 103 may be provided each comprising a component mounting area 104, 105 from which tie bars 106, 107, 152 extend into opposing directions, see FIG. 7. More specifically, it may be possible to provide an oblong carrier structure 132, such as a leadframe, comprising the integrally connected carriers 102, 103.

An electronic component 110, 111 may be mounted or assembled on each of the component mounting areas 104, 105 for example by soldering, sintering or electrically conductive glue (see FIG. 7).

Thereafter, it is possible to encapsulate the electronic components 110, 111 and part of the carriers 102, 103 by a respective encapsulant 112. During this process, the respective tie bars 106, 107, 152 are each clamped by an encapsulation tool pin 108, 109, 154 during the encapsulating process, see FIG. 7. More specifically, it may be possible to clamp on the respective tie bar 106, 107, 152 by the assigned encapsulation tool pin 108, 109, 154 during encapsulation so that the respective component mounting area 104, 105 is pressed onto a counter surface of an encapsulation tool 150 (see FIG. 9). Beneficially, encapsulating the electronic components 110, 111 and part of the carriers 102, 103 of oblong carrier structure 132 may be accomplished by an oblong encapsulant structure 130 to which said encapsulants 112 belong, as illustrated in FIG. 8. Said encapsulation process may be a molding process and said oblong encapsulant structure 130 may be an oblong bar of mold compound.

After said clamping during encapsulating and optionally also during curing encapsulants 112, each encapsulation tool pin 108, 109, 154 is removed from the respective tie bar 106, 107, 152 so that a respective horizontal surface portion of each tie bar 106, 107, 152 is exposed beyond the respective encapsulant 112.

Thereafter, a part of each tie bar 106, 107, 152 which corresponds to the respective exposed horizontal surface portion and an adjacent part of the respective encapsulant 112 is removed. This removal process may be accomplished by mechanically sawing using two sawing blades (see FIG. 10) during a singulation process by which a plurality of individual packages 100 are created.

During the singulation process, a structure obtained after encapsulation and removal of the encapsulation tool pins 108, 109, 154 may be separated into individual packages 100. Each package 100 may then comprise a respective one of said carriers 102, 103, a respective one of said electronic components 110, 111, and a part of said encapsulant structure 130 in form of a respective encapsulant 112. Advantageously, each of the obtained encapsulants 112 is formed with respective sidewalls 114, 115 as described above referring to FIG. 1 to FIG. 6 by a two-stage sawing process described below referring to FIG. 10.

During the described manufacturing method, two further slanted sidewalls 170, 172 of each encapsulant 112 may be formed and defined by a slanted sidewall 159 of a cavity 158 of an encapsulation tool 150, see FIG. 9. During the manufacturing method, it may be further possible to punch lead sections 124, 126 extending beyond each encapsulant 112 and being electrically coupled with the respective carrier 102, 103 and the respective electronic component 110, 111.

FIG. 10 illustrates a side view of an arrangement during manufacture of packages 100 using two different dicing blades 174, 176 according to an exemplary embodiment. For manufacturing sidewall 114 with a configuration according to FIG. 1 to FIG. 6, a two-stage dicing process may be executed, which comprises a first dicing process 191 using a first dicing blade 174 followed by a second dicing process 193 using a second dicing blade 176.

Starting point of the first dicing process 191 is a configuration in which a carrier 102 with component mounting area 104 carrying an electronic component 110 (not visible in FIG. 10) and having one or more tie bars 106 is encapsulated by an encapsulant 112 (see FIG. 8). During said encapsulation, it may be advantageous to temporarily clamp on the tie bar 106 by an encapsulation tool pin (see reference sign 108 in FIG. 7) so that the component mounting area 104 is pressed onto a counter surface of an encapsulation tool (not shown in FIG. 10, see reference sign 150 in FIG. 9). After encapsulation, the respective encapsulation tool pin 108 may be removed, leaving a pin hole 195 (which may also be denoted mold pin groove) behind. As shown in FIG. 10, a diameter of pin hole 195 is denoted as L and may for instance have a value of 0.5 mm.

For separation of individual packages 100 from a batch structure, the illustrated pre-form of the package 100 may be subjected to the first dicing process 191 using a first dicing blade 174 having a width D for removing a part of material of the tie bar 106 on and around pin hole 195. The result of this first dicing process 191 is shown on the right-hand side of FIG. 10 as a recess 197 extending vertically through the entire tie bar 106 and optionally slightly into the encapsulant 112. By this first dicing process 191, the step 160 and the second vertical sidewall section 164 with the exposed tie bar 106 may be defined.

Now referring to the second dicing process 193, the pre-form of the package 100 obtained after the first dicing process 191 is then subjected to the second dicing process 193 using a second dicing blade 176 having a width d for removing a part of material of the encapsulant 112 adjacent pin hole 195 to thereby define the first vertical sidewall section 162 and the notch 166. In the second dicing process 193, the encapsulant 112 is cut through its entire vertical thickness to thereby separate the individual packages 100 from each other.

In the illustrated embodiment, the first dicing blade 174 is provided with first width D and the second dicing blade 176 is provided with second width d being smaller than the first width D. Moreover, the first width D of the first dicing blade 174 may be larger than pin width L of the encapsulation tool pin 108 and correspondingly of the pin hole 195. For instance, said first width D is more than 0.5 mm, for example 0.55 mm. Said pin width L may be not more than 0.5 mm, for example 0.5 mm. The first width d may be for example less than 0.4 mm, for instance 0.3 mm. A cutting depth, x, of the first dicing blade 174 may be for example equal to or preferably larger than the thickness, y, of the tie bar 106. This may ensure that the first cutting blade 174 reliably cuts through the entire thickness of the tie bar 106. For example, the cutting depth x may be 3 mm, whereas the thickness y of the tie bar 106 may be 0.25 mm.

With the described two-stage cutting sequence using two different cutting blades 174, 176, it may be possible to prevent undesired insertion of debris or burr from the tie bar cutting process into the notch 166 which is created based on the pin hole 195 by the second dicing process 193. Particularly appropriate may be the combination of a first dicing process 191 using a first dicing blade 174 with a shallower and wider dicing path compared with a deeper and narrower dicing path in a second dicing process 193 using a second dicing blade 176.

Thus, an exemplary embodiments may introduce a two time cutting concept with different dicing blade thickness to generate sawing features to prevent copper debris trap inside the mold pin groove. Such a process may result in copper burr rejection after package sawing. At the same time, it may be possible to allow a fix mold pins design to serve as a clamping mechanism for a leadframe during transfer molding that may overcome or at least reduce the mold flash issue.

Thus, an exemplary embodiment may provide a fix mold pins design able to eliminate mold flash issues but generate tie bar copper debris caught inside mold pins groove after package sawing.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a carrier comprising a component mounting area from which a tie bar extends, the tie bar being configured for being clamped by an encapsulation tool pin during encapsulation;
an electronic component mounted on the component mounting area; and
an encapsulant encapsulating at least part of the electronic component and at least part of the carrier;
wherein a sidewall of the package has a step between a first vertical sidewall section and a second vertical sidewall section;
wherein the first vertical sidewall section has a notch in the encapsulant and a part of the second vertical sidewall section exposes the tie bar.

2. The package according to claim 1, wherein the sidewall has a horizontal sidewall section between the first vertical sidewall section and the second vertical sidewall section.

3. The package according to claim 2, wherein said horizontal sidewall section is delimited exclusively by material of the encapsulant.

4. The package according to claim 1, wherein said step extends entirely between two further sidewalls of the package connected to said sidewall.

5. The package according to claim 1, wherein said notch is delimited by a curved delimiting surface.

6. The package according to claim 1, wherein said notch is tapering towards the step.

7. The package according to claim 1, wherein an exposed surface of said tie bar extends from an upper end of said second vertical sidewall section towards the step.

8. The package according to claim 7, wherein said exposed surface of tie bar extends towards but not up to the step.

9. The package according to claim 1, wherein the notch and an exposed surface of the tie bar are in flush in a plan view on said sidewall.

10. The package according to claim 1, wherein the carrier comprises a further tie bar extending from the component mounting area and configured for being clamped by a further encapsulation tool pin during encapsulation, wherein another sidewall of the package has another step between another first vertical sidewall section and another second vertical sidewall section, wherein the other first vertical sidewall section has another notch in the encapsulant and a part of the other second vertical sidewall section exposes the other tie bar.

11. The package according to claim 10, wherein the tie bar and the further tie bar extend from opposing sides of the component mounting area, and wherein the sidewall and the other sidewall are opposing sidewalls of the package.

12. The package according to claim 1, wherein the sidewall is delimited exclusively by material of the encapsulant and of the tie bar.

13. The package according to claim 1, comprising at least one of the following features:
comprising one or more electrically conductive lead sections, in particular at least one of which being integrally formed with the component mounting area and/or at least one of which being formed separately from the component mounting area, extending out of the encapsulant at one or two slanted sidewalls of the encapsulant, said one or two slanted sidewalls in particular having a molded texture;
wherein a main surface of the component mounting area facing away from the electronic component is at least partially exposed with respect to the encapsulant;
wherein the sidewall has a sawn texture.

14. A method of manufacturing a package, the method comprising:
providing a carrier comprising a component mounting area from which a tie bar extends;
mounting an electronic component on the component mounting area;
encapsulating at least part of the electronic component and at least part of the carrier by an encapsulant, wherein the tie bar is clamped by an encapsulation tool pin during at least part of the encapsulating; and
forming the package with a sidewall which has a step between a first vertical sidewall section and a second vertical sidewall section;
forming the first vertical sidewall section with a notch in the encapsulant; and
exposing the tie bar at a part of the second vertical sidewall section.

15. The method according to claim 14, wherein the method comprises
subjecting a pre-form of the package to a first dicing process using a first dicing blade for removing a part of material of the tie bar; and
thereafter subjecting the pre-form of the package to a second dicing process using a second dicing blade for removing a part of material of the encapsulant.

16. The method according to claim 15, wherein the method comprises providing the first dicing blade of a first width and the second dicing blade of a second width smaller than the first width.

17. The method according to claim 15, wherein a first width of the first dicing blade is larger than a pin width of the encapsulation tool pin.

18. The method according to claim 17, wherein said first width is more than 0.5 mm and/or said pin width is not more than 0.5 mm.

19. The method according to claim 14, wherein the method comprises:
providing an oblong carrier structure comprising the carrier and at least one additional carrier comprising at least one additional component mounting area from which at least one additional tie bar extends;
mounting at least one additional electronic component on the at least one additional component mounting area;
encapsulating at least part of the at least one additional electronic component and part of the at least one additional carrier by an oblong encapsulant structure to which also said encapsulant belongs, wherein the at least one additional tie bar is clamped by at least one additional tool pin during at least part of the encapsulating; and
separating an obtained structure into individual packages each comprising a respective one of said carriers, a respective one of said electronic components, and a part of said encapsulant structure as a respective encapsulant, so that each of the packages is formed with a respective sidewall which has a respective step between a respective first vertical sidewall section and a respective second vertical sidewall section, wherein the respective first vertical sidewall section has a respective notch in the respective encapsulant and a part of the respective second vertical sidewall section exposes the respective tie bar.

20. The method according to claim 14, comprising at least one of the following features:
wherein the method comprises forming another slanted sidewall of the encapsulant by a slanted sidewall of a cavity of an encapsulation tool;
wherein the method comprises punching lead sections extending beyond the encapsulant and being electrically coupled with the carrier and/or the electronic component;
wherein the method comprises clamping on the tie bar by the encapsulation tool pin during encapsulation so that the component mounting area is pressed onto a counter surface of an encapsulation tool.
